(19) United States
(12) Patent Application Publication
(10) Pub. No.: US 2003/0006362 A1
(43) Pub. Date: Jan. 9, 2003

(54) Image scanning apparatus

(76) Inventors: Ta-Yi Lee, Shindian City (TW); Lung Chen, Shindian City (TW); Ming-Te Hung, Taipei (TW); Chang-Yao Lin, Tucheng City (TW)

Correspondence Address: SNELL & WILMER, ONE ARIZONA CENTER, 400 EAST VAN BUREN, PHOENIX, AZ, 850040001

(21) Appl. No.: 10/038,340

(22) Filed: Jan. 4, 2002

(30) Foreign Application Priority Data
Jul. 5, 2001 (TW) 090211323

(51) Int. Cl. H01L 27/00

(52) U.S. Cl. 250/208.1

(57) ABSTRACT

The present invention provides an image scanning apparatus, comprising: a housing including a first light source for a reflective-type scanning operation; and a cover rotatably connected to the housing and selectively covering the housing. The cover includes a second light source for a transparent-type scanning operation and a translucent case covering the second light source. When performing the reflective-type scanning operation, the translucent case provides a background to a reflective-type original. When performing the transparent-type scanning operation, the light from the second light source directly passes through the translucent case.

### BACKGROUND OF THE INVENTION

1. Field of the Invention

The present invention is related to an image scanning apparatus and, more particularly, to an image scanning apparatus capable of performing both the reflective-type and the transparent-type scanning.

2. Description of the Related Arts

Generally speaking, a scanner can be divided into three types: a reflective-type scanner for scanning reflective-type originals, such as paper documents; a transparent-type scanner for scanning transparent-type originals, such as films or filmstrips (slide or transparency); and a dual-function scanner for scanning the reflective-type originals and the transparent-type originals selectively.

FIG. 1(a) shows a conventional reflective-type scanner 1. The conventional reflective-type scanner 1 has a housing 11, a cover 13, and a board 12 connected to the cover 13. The housing 11 has a light source (not shown) for performing the reflective-type scanning operation. When performing the reflective-type scanning operation, the cover 13 covering on the upper surface of the housing 11 forces the board 12 to press against the original to be scanned. The board 12 usually is a sheet of plastic for pressing against the original to be scanned and for providing a background color.

In the recent years, with the price of scanners being much accepted by potential users and with the continuously upgraded image quality offered by scanners, dual-function scanners are widely used. Generally speaking, the conventional dual-function scanner is equipped with a cover together with a mask. When scanning the reflective-type original, the light source inside the housing is used. When scanning the transparent-type original, the light source inside the mask is used. Thus, when performing the reflective-type scanning operation, the light source inside the housing is used to illuminate the original to be scanned, and the image obtained enters an optical module in the housing. When performing the transparent-type scanning operation, the light source inside the mask is used to directly pass through the transparent-type original to be scanned, and the image obtained then enters the optical module in the housing.

In FIG. 1(b) shows a conventional dual-function scanner 2. The conventional dual-function scanner 2 has a housing 21 and a cover 23 together with a mask 22. The housing 21 has a light source (not shown) for performing the reflective-type scanning operation. The mask 22 also has a light source (not shown) for performing the transparent-type scanning operation. When performing the transparent-type scanning operation, the cover 23 covers on the upper surface of the housing 21, and the transparent-type original to be scanned lies between the cover 23 and the upper surface of the housing 21. The light from the light source inside the mask 22 passes through a translucent case 221 and impinges on the original to be scanned, and then the image obtained enters an optical module (not shown) in the housing 21.

With respect to the light source design of the mask of the dual-function scanner, approaches of either the back light module or the movable lamp are adopted. The advantages of using the back light include fewer components, smaller required space, lighter weight, non-requirement of drive mechanism, and less power consumption. However, the shortcoming is the much higher cost and, therefore, the small area module is adopted for reducing cost. The advantages of using the movable lamp include low cost and high luminance. However, the lamp must move synchronously with the optical module and cooperate with the optical module for the purpose of transparent scanning. Therefore, it needs a collocation of the drive mechanism, a larger space, and more components involved. Furthermore, the movable lamp approach usually adopts a transparent glass as a medium for positioning the original. The overall weight is much heavier.

While performing the reflective-type scanning operation by the dual-function scanner, to simplify a background in the scanning area, the following two methods are used. The first one is to additionally provide a cover without a mask for users to select the mask according to their need. That is, when scanning the transparent-type original, a cover with the mask is used, when scanning reflective-type original, a cover without the mask is used. The second approach is to additionally provide a sheet of black plastic cover or a PP/PVC board to cover the mask.

FIG. 2(a) shows a dual-function scanner 3 using a black plastic cover with a back light. This dual-function scanner 3 includes a housing 31, a cover 34 together with a mask 32, and a black plastic cover 33. The mask 32 has a back light 321 for supplying the light source when performing the transparent-type scanning operation. When performing the reflective-type scanning operation, the light source (not shown) in the housing 31 is used. Before the operation, the mask 32 is covered with the black plastic cover 33 for providing a black background to the reflective-type original to be scanned. When performing the transparent-type scanning operation, the black plastic cover 33 is removed from the mask 32 to use the light source of the back light 321.

FIG. 2(b) shows a dual-function scanner 4 using a black plastic cover with a movable lamp (not shown). This dual-function scanner 4 includes a housing 41, a cover 44 together with a mask 42, and a black plastic cover 43. The mask 42 has a movable lamp (not shown) for supplying the light source when performing the transparent-type scanning operation. When performing the reflective-type scanning operation, the black plastic cover 43 covers on the mask 42 for providing a black background to the reflective-type original to be scanned. When performing the transparent-type scanning operation, the black plastic cover 43 is removed from the mask 42 to use the movable lamp inside the mask 42.

Although the prior arts solve the background simplification problem of the reflective-type scanning operation, however, the conventional approach still has issues of heavier weight, the high cost, and too many components. There is a need to provide a simpler design to improve this problem.

### SUMMARY OF THE INVENTION

For solving problems mentioned above, the present invention provides an image scanning apparatus capable of performing both the reflective-type and the transparent-type scanning. There is no need to additionally change the cover or add the black plastic cover when performing the reflective-type scanning operation. Therefore, inconveniences during use may substantially be reduced.

One objective of the present invention, through simple design without additional apparatus, is to switch between the reflective-type scanning operation and the transparent-type scanning operation. Therefore, the present invention provides an image scanning apparatus including a housing having a first light source for the reflective-type scanning operation, and a cover rotatably connected to the housing selectively covering the housing. The cover includes a second light source for the transparent-type scanning operation, and a translucent case covering the second light source. When performing the reflective-type scanning operation, the translucent case provides a background to a reflective-type original to be scanned, and makes the light of the first light source from the housing be reflected into the optical module in the housing. When performing the transparent-type scanning operation, the light from the second light source directly passes through the translucent case.

The further objectives and advantages of the present invention can be further understood by referring to the following detailed description of the invention and drawings.

### BRIEF DESCRIPTION OF THE DRAWINGS

FIG. 1(a) shows a conventional scanner of a reflective-type original;

FIG. 1(b) shows a conventional dual-function scanner;

FIG. 2(a) shows a conventional dual-function scanner using a black plastic cover with a back light;

FIG. 2(b) shows a conventional dual-function scanner using a black plastic cover with a movable lamp;

FIG. 3 shows a dual-function scanner of an embodiment of the present invention;

FIG. 4(a) shows a diagram of a reflective-type scanning operation of an embodiment of the present invention; and

FIG. 4(b) shows a diagram of a transparent-type scanning operation of an embodiment of the present invention.

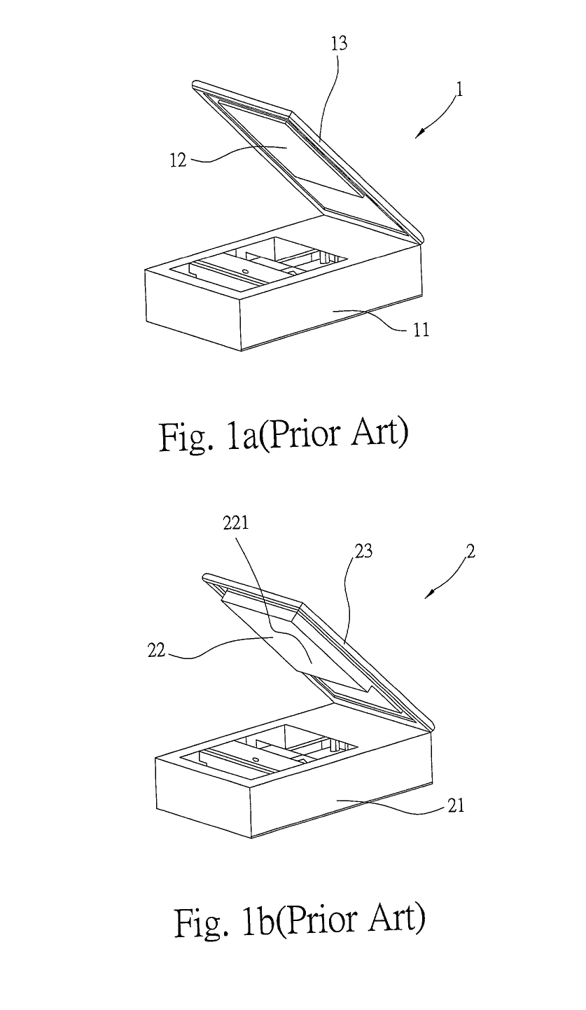

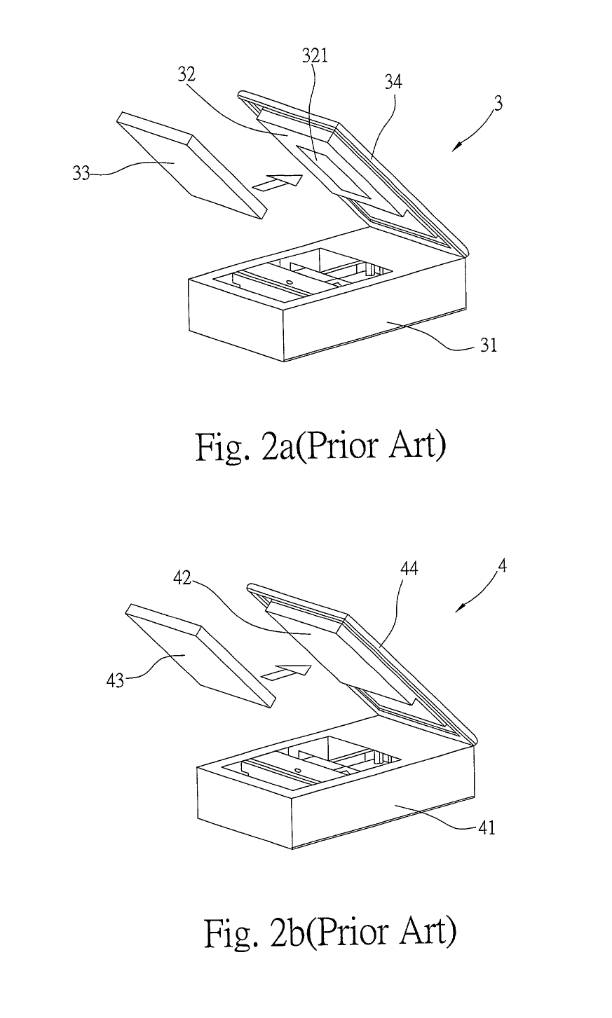

### DETAILED DESCRIPTION OF THE INVENTION

The present invention covers on a mask (a movable lamp or a back light) of a scanner with a case made by translucent materials, such as glass or plastic. Users can switch between the reflective-type scanning operation and the transparent-type scanning operation without changing the cover or adding additional apparatus. That is, when performing the reflective-type scanning operation, the white (or other color) surface of the translucent case provides a background to the original to be scanned. The light from the housing will not enter the structure inside the mask. When performing the transparent-type scanning operation, a light from the mask passes through the translucent case and impinges on the transparent-type original to be scanned, and then the image obtained enters an optical module.

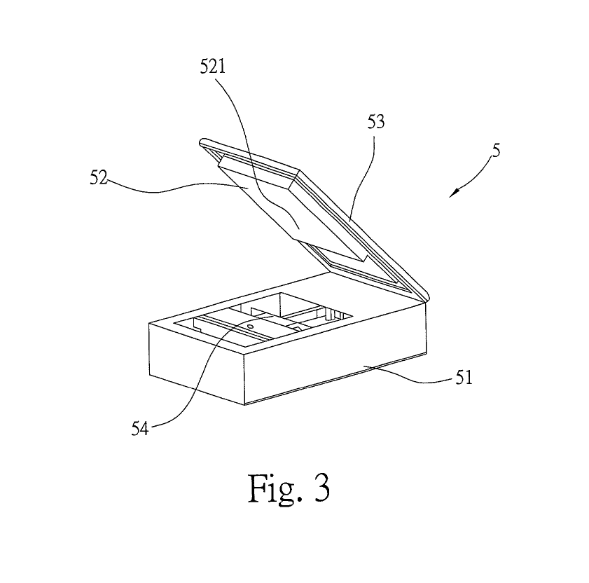

Please refer to FIG. 3. FIG. 3 shows a dual-function scanner 5 of an embodiment of the present invention. The dual-function scanner 5 has a housing 51 and a cover 53 together with a mask 52. The cover 53 is rotatably connected to the housing 51 and selectively covering on the housing 51. The housing 51 has a first light source (not shown) for performing the reflective-type scanning operation. The cover 53 has a second light source (not shown), which could be a back light or a movable lamp, for the transparent-type scanning operation. The surface of the mask 52 is covered with a translucent case 521. The translucent case 521 with appropriate transparency allows the light from the second light source to pass through the translucent case 521. In the embodiment of the present invention, the translucent case 521 is a white translucent case made by plastic.

When performing the reflective-type scanning operation, the cover 53 covers on the housing 51, and the reflective-type original is placed on the glass 54 over the upper surface of the housing 51. The translucent case 521 provides a background to the reflective-type original to be scanned. When performing the transparent-type scanning operation, the cover 53 covers on the housing 51, and the transparent-type original is placed on the glass 54 over the upper surface of the housing 51. The light from the second light source passes through the translucent case 521, the transparent-type original to be scanned, and the glass 54, and then the image obtained enters the optical module (not shown) in the housing 51.

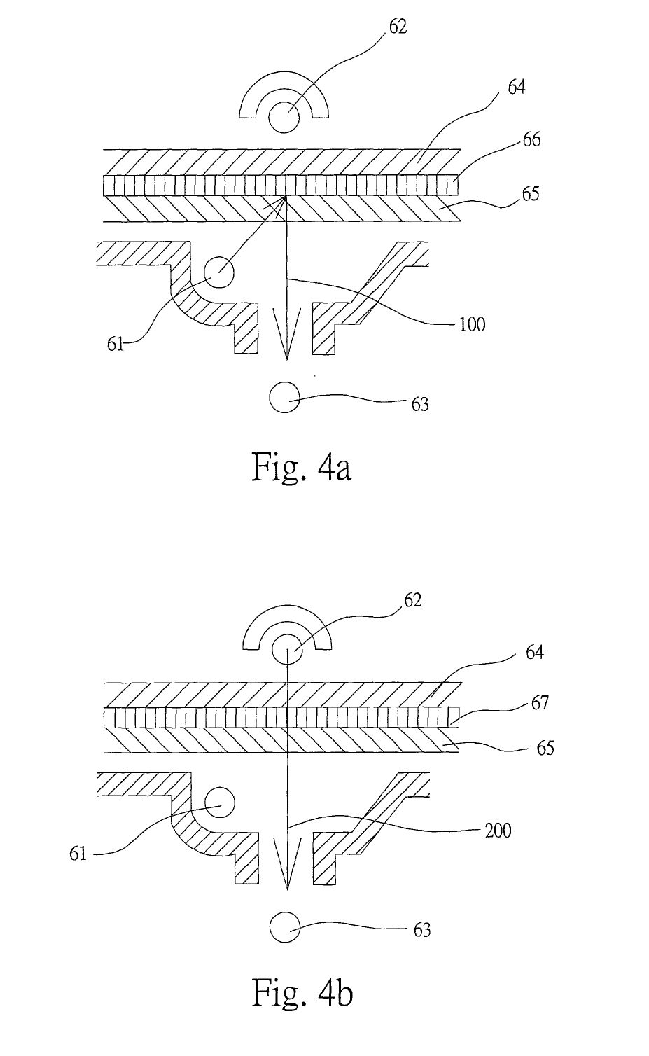

Please refer to FIG. 4(a) and FIG. 4(b). FIG. 4(a) shows a diagram of the reflective-type scanning operation of an embodiment of the present invention. A reflective-type original 66 is placed between a glass 65 over the upper surface of the housing and a translucent case 64. When performing the reflective-type scanning operation, a second light source 62 is OFF, and a first source light 61 is ON. The light 100 from the first light source 61 passes through the glass 65 and is reflected into an optical module 63 by the reflective-type original 66. Since the translucent case 64 has appropriate transparency, the light 100 from the first light source 61 will not scan the structure inside the second light source 62, and the translucent case 64 provides a background to the reflective-type original 66.

FIG. 4(b) shows a diagram of the transparent-type scanning operation of an embodiment of the present invention. A transparent-type original 67 is placed between the glass 65 over the upper surface of the housing and the translucent case 64. When performing the transparent-type scanning operation, the first light source 61 is OFF, and the second light source 62 is ON. Since the translucent case 64 has appropriate transparency, the light 200 from the second light source 62 passes through the translucent case 64 and impinges on the transparent-type original 67 and the glass 65. Then, the image obtained is received by the optical module 63.

Besides, the transparency of the translucent case 64 may vary according to the practical characteristic of the second light source. Therefore, it not only makes the control of the luminance and the spectrum more flexible, but also spreads the light source to achieve more uniform luminance and band.

In the foregoing specification the invention has been illustrated with preferred embodiments, but it is not intended to limit the present invention. Any persons skilled in the art may make various modifications and changes without departing from the spirit and the scope of the present invention. For example, the translucent case is a white translucent case made by plastic in an embodiment of the present invention, yet it is not intended to limit the material, other materials or colors still can implement the present invention. Therefore, the protective scope of the present invention should be interpreted based on the following claims.

What is claimed is:

1. An image scanning apparatus, comprising:
a housing including a first light source for a reflective-type scanning operation; and
a cover rotatably connected to said housing and selectively covering said housing, comprising:
a second light source for a transparent-type scanning operation; and
a translucent case covering said second light source.

2. The image scanning apparatus according to claim 1, wherein said translucent case provides a background to a reflective-type original when performing said reflective-type scanning operation.

3. The image scanning apparatus according to claim 1, wherein a light from said second light source passes through said translucent case when performing said transparent-type scanning operation.

4. The image scanning apparatus according to claim 1, wherein said second light source is a movable lamp.

5. The image scanning apparatus according to claim 1,
wherein said second light source is a back light.

6. The image scanning apparatus according to claim 1,
wherein said translucent case comprises a plastic.

7. The image scanning apparatus according to claim 1, wherein said translucent case comprises glass.

8. A cover for use with an image scanning apparatus, said image scanning apparatus having a housing with a first light source for a reflective-type scanning operation, said cover being rotatably connected to said housing and selectively covering said housing, said cover comprising:
a second light source for a transparent-type scanning operation; and
a translucent case covering said second light source.

9. The cover according to claim 8, wherein said translucent case provides a background to a reflective-type original when performing said reflective-type scanning operation.

10. The cover according to claim 8, wherein a light from said second light source passes through said translucent case when performing said transparent-type scanning operation.

11. The cover according to claim 8, wherein said second light source is a movable lamp.

12. The cover according to claim 8, wherein said second light source is a back light.

13. The cover according to claim 8, wherein said translucent case comprises a plastic.

14. The cover according to claim 8, wherein said translucent case comprises a glass.
